(19) United States
(12) Patent Application Publication
(10) Pub. No.: US 2024/0166567 A1
(43) Pub. Date: May 23, 2024

(54) COMPOSITE STRUCTURE AND SEMICONDUCTOR MANUFACTURING DEVICE PROVIDED WITH THE COMPOSITE STRUCTURE

(71) Applicant: TOTO LTD., KITAKYUSHU-SHI, FUKUOKA (JP)

(72) Inventors: Hiroaki ASHIZAWA, KITAKYUSHU-SHI, FUKUOKA (JP); Ryoto TAKIZAWA, KITAKYUSHU-SHI, FUKUOKA (JP)

(21) Appl. No.: 18/282,857

(22) PCT Filed: Mar. 17, 2022
(86) PCT No.: PCT/JP2022/012151

§ 371 Date: Sep. 19, 2023

(30) Foreign Application Priority Data
Mar. 29, 2021 (JP) 2021-055621
Sep. 25, 2021 (JP) 2021-156217
Feb. 8, 2022 (JP) 2022-017677

(51) Int. Cl. C04B 35/44; C23C 24/04

(52) U.S. Cl. CPC C04B 35/44; C04B 2235/3218; C04B 2235/781; C23C 24/04

(57) ABSTRACT

Disclosed are a composite structure, which is able to enhance low-particle generation so that this can be used as a member for a semiconductor manufacturing device, and a semiconductor manufacturing device provided with the composite structure. The composite structure has a substrate and a structure that is provided on the substrate and has a surface, in which the structure contains Y₄Al₂O₉ as a main component, and an indentation hardness thereof is greater than 6.0 GPa, thereby having excellent low-particle generation, so that this may be suitably used as a member for a semiconductor manufacturing device.

### TECHNICAL FIELD

The present invention relates to a composite structure having an excellent low-particle generation that is suitably used as a member for a semiconductor manufacturing device and relates to a semiconductor manufacturing device equipped with the composite structure.

### BACKGROUND ART

There has been known a technology with which a substrate is imparted with a function by means of coating a surface thereof with ceramics. For example, as a member for a semiconductor manufacturing device that is used in a plasma irradiation environment such as a semiconductor manufacturing device, the member having the surface thereof coated with a highly plasma-resistant film is used. For the coating, for example, oxide-based ceramics such as alumina (Al₂O₃) and yttria (Y₂O₃), and fluorides such as yttrium fluoride (YF₃) and yttrium oxyfluoride (YOF) are used.

Further, as the oxide-based ceramics, it has been proposed to use a protective layer using erbium oxide (Er₂O₃) or Er₃Al₅O₁₂, gadolinium oxide (Gd₂O₃) or Gd₃Al₅O₁₂, yttrium aluminum garnet (YAG: Y₃Al₅O₁₂) or Y₄Al₂O₉, etc. (Patent Literatures 1 and 2). With advancement of miniaturization in a semiconductor, a higher level of low-particle generation is required for various members inside the semiconductor manufacturing device.

### CITATION LIST

### Patent Literatures

[PTL 1] JP2016-528380A
[PTL 2] JP2017-514991A

### SUMMARY OF THE INVENTION

### Technical Problem

We have now found that there is a relationship between hardness of a structure containing as a main component therein an oxide of yttrium and aluminum, Y₄Al₂O₉ (hereinafter abbreviated as “YAM”), and low-particle generation, which is the index of particle contamination associated with plasma corrosion; and as a result, they succeeded to obtain a structure having excellent low-particle generation.

Accordingly, the present invention provides a composite structure having excellent low-particle generation. A further object of the present invention relates to the use of this composite structure as a member for a semiconductor manufacturing device and to providing a semiconductor manufacturing device using this composite structure.

### Solution to Problem

The composite structure according to the present invention is a composite structure comprising a substrate and a structure which is provided on the substrate and has a surface, in which the structure contains Y₄Al₂O₉ as a main component, and an indentation hardness thereof is greater than 6.0 GPa.

Further, the composite structure according to the present invention is used in an environment where low-particle generation is required.

Further, the semiconductor manufacturing device according to the present invention is equipped with the composite structure according to the present invention as described above.

### BRIEF DESCRIPTION OF THE DRAWINGS

FIG. 1 is a schematic cross-sectional view of a member having the structure according to the present invention.

FIG. 2 is a graph showing the relationship between the depth from the structure surface and the fluorine atom concentration after the standard plasma test 1.

FIG. 3 is a graph showing the relationship between the depth from the structure surface and the fluorine atom concentration after the standard plasma test 2.

FIG. 4 is SEM images of the structure surfaces after the standard plasma tests 1 and 2.

### DESCRIPTION OF THE EMBODIMENTS

Composite Structure

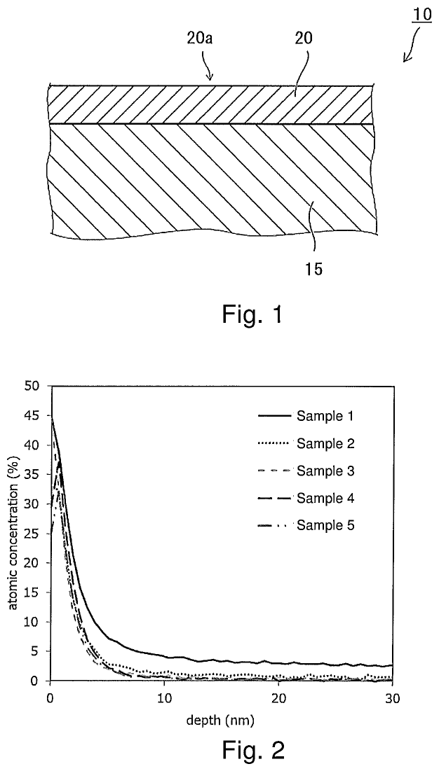

A basic structure of the composite structure according to the present invention will be described with referring to FIG. 1. FIG. 1 is a schematic cross-sectional view of a composite structure 10 according to the present invention. The composite structure 10 is comprised of a structure 20 provided on a substrate 15, in which the structure 20 has a surface 20a.

The structure 20 provided by the composite structure according to the present invention is a so-called ceramic coat. By forming the ceramic coat, it is possible to impart various physical properties and characteristics to the substrate 15. In this specification, the structure (or ceramic structure) and the ceramic coat are used interchangeably unless otherwise specifically mentioned.

The composite structure 10 is arranged, for example, inside a chamber of a semiconductor manufacturing device having a chamber. The composite structure 10 may constitute an inner wall of the chamber. Inside the chamber, SF or CF fluorine gases are introduced to generate plasma, so that the surface 20a of the structure 20 is exposed to the plasma atmosphere. Therefore, the low-particle generation is required for the structure 20 on the surface of the composite structure 10. Further, the composite structure according to the present invention can be used as a member mounted on other than the inside of the chamber. In this specification, the semiconductor manufacturing device in which the composite structure according to the present invention is used means any semiconductor manufacturing device (semiconductor processing device) that performs processing such as annealing, etching, sputtering, CVD, etc.

Substrate

In the present invention, the substrate 15 can be comprised of alumina, quartz, anodized aluminum, metal, glass, or the like, and is preferably comprised of alumina, but not limited thereto as long as it is used for its use. According to a preferred embodiment of the present invention, the arithmetic average roughness Ra (JISB0601: 2001) of the surface of the substrate 15 on which the structure 20 is formed is, for example, less than 5 micrometers (μm), preferably less than 1 μm, and more preferably less than 0.5 μm.

Structure

In the present invention, the structure includes YAM as the main component therein. Further, according to one embodiment of the present invention, YAM is polycrystalline.

In the present invention, the main component of the structure refers to the compound that is contained relatively more than other compounds contained in the structure 20 by quantitative or quasi-quantitative analysis with X-ray diffraction (X-ray Diffraction: XRD) of the structure. For example, the main component is the compound most contained in the structure, and the ratio occupied by the main component in the structure is greater than 50% in volume ratio or mass ratio. The ratio occupied by the main component is more preferably greater than 70%, and preferably greater than 90% as well. The ratio occupied by the main component may be 100%.

In the present invention, components that the structure may contain in addition to YAM include oxides such as yttrium oxide, scandium oxide, europium oxide, gadolinium oxide, erbium oxide, ytterbium oxide, as well as fluorides such as yttrium fluoride and yttrium oxyfluoride, and may include a plurality of two or more of these.

In the present invention, the structure is not limited to a single-layer structure and may be a multi-layer structure. A plurality of layers having, as the main component, YAM that has different compositions may be formed; and thus, another layer, for example, a layer containing Y₂O₃ may be formed between the substrate and the structure.

Indentation Hardness

In the present invention, the structure containing YAM as the main component has an indentation hardness of greater than 6.0 GPa. Thereby, the low-particle generation can be enhanced. According to a preferred embodiment of the present invention, the indentation hardness is 9 GPa or greater, more preferably 10 or greater, and even more preferably 11 GPa or greater. There is no particular restriction in the upper limit of the indentation hardness, so that this may be determined according to required characteristics; but, for example, this is 20 GPa or less.

The indentation hardness of the structure is measured as follows. That is, the hardness is measured by a nanoindentation hardness test to the surface of the structure containing YAM as the main component provided on the substrate. Using a Berkovich indenter with the fixed indenting depth of 200 nm, the indentation hardness H_{IT} is measured. The surface excluding portions having a scar or a dent is chosen as the H_{IT} measurement location. More preferably, a polished, flat and smooth surface is chosen. The measurement spots of at least 25 or more are chosen. The average H_{IT} value of the 25 or more measured spots is used as the hardness in the present invention. Other testing and analysis methods, procedure to investigate performance of a testing apparatus, and conditions required for a standard reference sample conform to ISO 14577.

In the semiconductor manufacturing device, highly corrosive fluorine-based plasmas such as a CF-based gas and a SF-based gas are used. The structure according to the present invention containing YAM as the main component is less changed in its crystal structure by exposure to these fluorine-based plasmas. Accordingly, even when used with being exposed to the corrosive plasma, it is though that the change of the crystal structure in the structure surface can be suppressed, so that lower particle generation can be realized.

According to one embodiment of the present invention, when the YAM contained in the structure is polycrystalline, the average crystallite's size thereof is, for example, less than 100 nm, preferably less than 50 nm, more preferably less than 30 nm, and most preferably less than 20 nm. With smaller crystallite's size, the particles generated by plasma may be made smaller.

In this specification, “polycrystal” means the structure having crystal particles bonded and aggregated. Here, it is preferable that the crystal particles be formed by substantially one crystal, in which the diameter of the crystal particle is, for example, 5 nanometers (nm) or greater.

In the present invention, the crystallite's size is measured by, for example, X-ray diffraction. The crystallite's size can be calculated as the average crystallite's size by the Scherrer's equation below:

D=Kλ/(β cos θ)

wherein D is the crystallite's size, β is a peak's half-width (unit: radian (rad)), θ is a Bragg's angle (unit: rad), and λ is a characteristic X-ray wavelength using XRD.

In the Scherrer's equation, β is calculated by β=(βobs−βstd). Here, βobs is a half-width of the X-ray peak of the measuring sample, and βstd is a half-width of the X-ray peak of the standard sample. K is a Scherrer's constant.

In YAM, the X-ray diffraction peaks that can be used to calculate the crystallite's size are the peak near the diffraction angle 2θ=26.7°, which is attributable to the Miller indices (hkl)=(013), the peak near the diffraction angle 2θ=29.6°, which is attributable to the Miller indices (hkl)=(122), the peak near the diffraction angle 2θ=30.6°, which is attributable to the Miller indices (hkl)=(211), etc., in the YAM monoclinic crystal.

Furthermore, the crystallite's size can be also calculated from the image that is obtained by observation with a transmission electron microscope (TEM). For example, an average value of the crystallite's circle-equivalent diameters may be used as the average crystallite's size.

In an embodiment in which YAM is polycrystalline, the distance between the crystallites present adjacent to each other is preferably 0 nm or greater and less than 10 nm. The distance between the crystallites present adjacent to each other means the smallest distance between the crystallites, not including the space formed by a plurality of crystallites. The distance between the crystallites can be obtained from the image that is obtained by TEM observation.

Fluorine Invasion Depth

According to a preferred embodiment of the present invention, the structure formed in the composite structure according to the present invention shows preferable low-particle generation, which is the property that a fluorine atom concentration at a prescribed depth from the surface thereof is lower than a prescribed value upon exposed to a specific fluorine-based plasma. The composite structure according to this embodiment of the present invention meets the fluorine atom concentration at the depth from each surface described below after exposed to the fluorine-based plasma under following two conditions. In the present invention, the fluorine-based plasma exposure tests under the two conditions are respectively called standard plasma tests 1 and 2.

The standard plasma tests 1 and 2 are based on various conditions assumed in the semiconductor manufacturing device. The standard plasma test 1 is based on the assumed condition of being applied with biased voltage in which the structure is used as a member such as a focus ring that is located around a silicon wafer inside of a chamber thereby being exposed to a corrosive environment due to a radical and an ion collision. The standard plasma test 1 evaluates the performance to the SF 6 plasma. On the other hand, the standard plasma test 2 is based on the condition not being applied with a bias, in which the structure is used as a sidewall member located almost vertically to a silicon wafer in a chamber or as a ceiling member located facing to the silicon wafer; thus, this is the test condition assuming to be exposed to a corrosion environment mainly due to a radical with less ion collision. According to a preferred embodiment of the present invention, the composite structure according to the present invention meets at least one prescribed value of the fluorine concentration in these tests.

(1) Plasma Exposure Condition

Using the structure including YAM as the main component formed on the substrate, the surface thereof is exposed to a plasma environment using an inductively coupled reactive ion etching (ICP-RIE) apparatus. Following two conditions are used to form the plasma environment.

Standard Plasma Test 1:

Process gas of SF₆ 100 sccm, coil output of 1500 W for ICP as the source output, and bias output of 750 W are used.

Standard Plasma Test 2:

Process gas of SF₆ 100 sccm, coil output of 1500 W for ICP as the source output, and off bias output (0 W) are used. That is, a high frequency power for static chuck bias is not applied.

In both the standard plasma tests 1 and 2, the chamber pressure of 0.5 Pa and the plasma exposure time of 1 hour are used. The semiconductor manufacturing device member is disposed on the silicon wafer attached by means of a static chuck that is arranged in the inductively coupled reactive ion etching apparatus in such a way that the structure surface may be exposed to the environment.

(2) Measurement Method of Fluorine Atom Concentration in Depth Direction from Structure Surface

With regard to the structure surface after the standard plasma tests 1 and 2, by using an X-ray photoelectron spectroscopy (XPS) the fluorine (F) atom concentration (%) versus sputtering time was measured by the depth direction analysis using ion sputtering. Subsequently, in order to convert the sputtering time to the depth, the level difference (s) between the places sputtered by ion sputtering and unsputtered was measured by a stylus surface profilometer. From the level difference (s) and the total sputtering time (t) used for the XPS measurement, the depth (e) versus the sputtering unit time is calculated by e=s/t; then, the sputtering time is converted to the depth using the depth (e) versus the sputtering unit time. Finally, the depth from the surface 20a and the fluorine (F) atom concentration (%) at this depth are calculated.

In this embodiment, after the standard plasma tests 1 and 2, the composite structure according to the present invention meets both the fluorine atom concentrations from the respective surfaces described below.

After Standard Plasma Test 1:

The fluorine atom concentration F1_{10 nm} at 10 nm from the surface is less than 3.0%, preferably F1_{10 nm} is 1.5% or less, and more preferably F1_{10 nm} is 1.0% or less.

After Standard Plasma Test 2:

The fluorine atom concentration F3_{10 nm} at 10 nm from the surface is less than 3.0%, preferably F3_{10 nm} is 1.0% or less, and more preferably F3_{10 nm} is 0.5% or less.

Production of Composite Structure

The composite structure according to the present invention may be produced by any appropriate production method as long as the structure having the lattice constants described above can be formed on the substrate. That is, the composite structure may be produced by the method with which the structure containing Y₄Al₂O₉ as the main component and having the lattice constants described above can be formed on the substrate; so, for example, the structure may be formed on the substrate by a physical vapor deposition method (PVD method) and a chemical vapor deposition method (CVD method). Illustrative examples of the PVD method include an electron beam physical vapor deposition (EB-PVD) method, an ion beam-assisted vapor deposition (IAD) method, an electron beam ion-assisted vapor deposition (EB-IAD) method, an ion plating method, and a sputtering method. Illustrative examples of the CVD method include a thermal CVD method, a plasma CVD (PECVD) method, an organometallic CVD (MOCVD) method, a mist CVD method, a laser CVD method, and an atomic layer deposition (ALD) method. Further, according to another embodiment of the present invention, fine particles such as brittle materials are disposed on the substrate surface followed by imparting a mechanical impact force to the fine particles. In the “mechanical impact force imparting” method is used a compression force by a shock wave generated by explosion, using, among others, a brush or a roller that rotates rapidly or a piston that rapidly moves up-and-down, these having very high hardness. Also, usable is application of a microwave, or combinations of these.

Further, the composite structure according to the present invention may be suitably formed by an aerosol deposition method (AD method). In the “AD method”, “aerosol” that is formed by dispersing fine particles containing brittle materials such as ceramics is injected to the substrate from a nozzle thereby colliding the fine particles to the substrate such as metal, glass, ceramics, or plastics at a high speed so as to deform or crush the brittle fine particles due to the collision impact thereby bonding them to directly form the structure including fine particles of the constituent material (ceramic coat) on the substrate as a layered structure or a filmed structure, for example. With this method, the structure can be formed at normal temperature without requiring heating or cooling means, in which the structure having the mechanical strength equivalent to or even higher than a sintered structure can be obtained. In addition, by controlling the collision condition, shape, composition, etc. of the fine particles, properties such as density, mechanical strength, and electrical properties of the structure can be variously changed. Then, by setting the conditions described below such that the indentation hardness may be met thereby realizing the composite structure according to the present invention, it is possible to produce the composite structure according to the present invention.

In this specification, “fine particles” means, when the primary particle is a compact particle, the average particle diameter measured by size distribution measurement or identified by scanning electron microscope is 5 micrometers (μm) or less. When the primary particle is a porous particle that can be readily broken by impact, this means the average particle diameter is 50 μm or less.

Further, in this specification, “aerosol” means the solid-gas mixed phase having the fine particles described above dispersed in a gas (gas carrier) such as helium, nitrogen, argon, oxygen, dried air, or a mixed gas of these, and includes “aggregate”, but preferably in the state in which the fine particles are substantially and independently dispersed. The gas pressure and temperature of the aerosol may be arbitrarily determined in view of physical properties, etc. of the intended structure; but the fine particle concentration in the gas at the time of injection from an injection port is preferably in the range of 0.0003 mL/L to 5 mL/L in terms of the gas pressure of 1 atm and the temperature of 20° C.

In general, the aerosol deposition process is carried out at normal temperature. It is possible to form the structure at the temperature substantially lower than the melting point of the fine particle material, that is, lower than some hundred degrees Celsius. In this specification, “normal temperature” means the temperature remarkably lower than the ceramics sintering temperature; so, this means a room temperature environment substantially in the range of 0 to 100° C. In this specification, “powder” means the state in which the fine particles described above naturally aggregate.

### Examples

The present invention will be further elaborated by the following Examples, but the present invention is not limited to these Examples.

The raw material of the structure used in Examples is described in the Table below.

TABLE 1

| | | D50 |
|---|---|---|
| Raw material | Composition | (μm) |
| F1 | Y₄Al₂O₉ | 2.2 |

In the Table, the median diameter (D50 (μm)) means the diameter at 50% in the cumulative particle size distribution of each raw material. The diameter of each particle was the diameter determined by sphere approximation.

By changing the combination with filming conditions (type of carrier gas, flow rate thereof, etc.), a plurality of samples having the structure provided on the substrate was prepared. The low-particle generation properties of the resulting samples after the standard plasma tests 1 and 2 were evaluated. In these examples, the samples were prepared by the aerosol deposition method.

TABLE 2

| | | | Flow | Film | | Plasma corrosion | | |
|---|---|---|---|---|---|---|---|---|
| | Raw | | rate | thickness | Hardness | | | Total |
| Sample | material | Gas | (L/min) | (μm) | (Gpa) | Test 1 | Test 2 | evaluation |
| 1 | F1 | N₂ | 2.5 | 6.2 | 6.0 | X | X | X |
| 2 | F1 | N₂ | 5 | 5.2 | 9.0 | Δ | Δ | Δ |
| 3 | F1 | N₂ | 7 | 5.4 | 9.6 | ◯ | ◯ | ◯ |
| 4 | F1 | N₂ | 10 | 8.4 | 11.2 | ⊚ | ⊚ | ⊚ |
| 5 | F1 | N₂ | 10 | 5.7 | 11.1 | ⊚ | ⊚ | ⊚ |
| 6 | F1 | He | 30 | 7.5 | 11.4 | ⊚ | ⊚ | ⊚ |

As illustrated in the table, nitrogen (N₂) or helium (He) is used as the carrier gas. The aerosol is obtained by mixing the carrier gas with the raw material powder (raw material fine particles) in an aerosol generator. By a pressure difference the resulting aerosol is ejected from a nozzle connected to the aerosol generator toward the substrate that is disposed inside of a filming chamber. At this time, an air in the filming chamber is discharged to outside by means of a vacuum pump.

Sample

All the resulting structure samples 1 to 5 contained polycrystalline YAM as the main component, and all the average crystallite's sizes in these polycrystals were less than 30 nm.

The crystallite's size was measured using XRD. That is, “X'Pert Pro, manufactured by Panalytical” was used as the XRD apparatus. The XRD measurement conditions with the characteristic X-ray of CuKα (λ=1.5418 Å), the tube voltage of 45 kV, the tube current of 40 mA, the Step Size of 0.0084°, and the Time per Step of 80 seconds or longer were used. As the average crystallite's size, the crystallite's size was calculated by the Scherrer's equation. The value of 0.94 was used as the K value in the Scherrer's equation.

The main component in the crystal phase of YAM on the substrate was measured by means of XRD. “X'Pert Pro, manufactured by Panalytical” was used as the XRD apparatus. The XRD measurement conditions with the characteristic X-ray of CuKα (λ=1.5418 Å), the tube voltage of 45 kV, the tube current of 40 mA, the Step Size of 0.0084°, and the Time per Step of 80 seconds or longer were used. For calculation of the main component, XRD analysis software “High Score Plus, manufactured by Panalytical” was used. Using the semi-quantitative value (RIR: Reference Intensity Ratio) in the ICDD card, the calculation was conducted with the reference intensity ratio obtained at the time of peak search in the diffraction peaks. In the measurement of YAM polycrystalline main component in the laminated structure, it is desirable to use the measurement result by the thin film XRD in the depth region of less than 1 μm from the outermost surface.

Standard Plasma Tests

The low-particle generation properties of the samples 1 to 5 after the standard plasma tests 1 and 2 under the before-mentioned conditions were evaluated by the procedure described below. “Muc-21 Rv-Aps-Se, manufactured by Sumitomo Precision Products Co., Ltd.” was used as the ICP-RIE apparatus. In both the standard plasma tests 1 and 2, the conditions with the chamber pressure of 0.5 Pa and the plasma exposure time of 1 hour were used. The sample was disposed on the silicon wafer attached by means of a static chuck that is arranged in the inductively coupled reactive ion etching apparatus in such a way that the sample surface might be exposed to the plasma environment formed by the above-mentioned condition.

Measurement of Indentation Hardness

With the nanoindentation hardness test, the indentation hardness of the structure on the substrate was evaluated by the following procedure. “ENT-2100 manufactured by Elionix” was used as the nanoindenter. As the condition for the nanoindentation hardness test, using a Berkovich indenter, the test mode of indenting depth setting with the indenting depth of 200 nm was used. Then, the indentation hardness H_{IT} was measured. Measurement spots of H_{IT} were randomly chosen on the structure surface, in which the measurement spots of at least 25 or more were chosen. The average H_{IT} value of the 25 or more measured spots was used as the hardness. The results are listed in Table 2.

Measurement of Fluorine Invasion Depth

With regard to the sample surface after the standard plasma tests 1 and 2, by using an X-ray photoelectron spectroscopy (XPS), the fluorine (F) atom concentration (%) versus sputtering time was measured by the depth direction analysis using ion sputtering. “K-Alpha, manufactured by Thermo Fisher Scientific” was used as the XPS apparatus. Subsequently, in order to convert the sputtering time to the depth, the level difference (s) between the places sputtered by ion sputtering and unsputtered was measured by a stylus surface profilometer. From the level difference (s) and the total sputtering time (t) used for the XPS measurement, the depth (e) versus the sputtering unit time was calculated by e=s/t; then, the sputtering time was converted to the depth using the depth (e) versus the sputtering unit time. Finally, the depth from the sample surface and the fluorine (F) atom concentration (%) at this depth were calculated.

The depth from the structure surface and the fluorine atom concentration after the standard plasma tests 1 and 2 were described in the below tables.

### After the Standard Plasma Test 1:

TABLE 3

| | Standard plasma test 1 | | | | |
|---|---|---|---|---|---|
| Sample | 30 nm | 20 nm | 15 nm | 10 nm | 5 nm |
| 1 | 2.71 | 2.98 | 3.35 | 3.93 | 7.17 |
| 2 | 0.83 | 0.96 | 1.06 | 1.64 | 2.81 |
| 3 | 0.54 | 0.63 | 0.49 | 1.01 | 1.95 |
| 4 | 0.19 | 0 | 0.29 | 0.62 | 2.17 |
| 5 | 0.48 | 0.24 | 0.36 | 0.59 | 2.09 |
| 6 | 0.16 | 0.25 | 0.26 | 0.28 | 2.08 |

### After the Standard Plasma Test 2:

TABLE 4

| | Standard plasma test 2 | | | | |
|---|---|---|---|---|---|
| Sample | 30 nm | 20 nm | 15 nm | 10 nm | 5 nm |
| 1 | 2.48 | 3.4 | 3.04 | 3.47 | 5.89 |
| 2 | 0.35 | 0.73 | 0.48 | 0.8 | 3.04 |
| 3 | 0.55 | 0.08 | 0.33 | 0.6 | 2.24 |
| 4 | 0.11 | 0.44 | 0.54 | 0.46 | 2.28 |
| 5 | 0 | 0.39 | 0.46 | 0.44 | 3.39 |
| 6 | 0 | 0.44 | 0.58 | 0.82 | 4.97 |

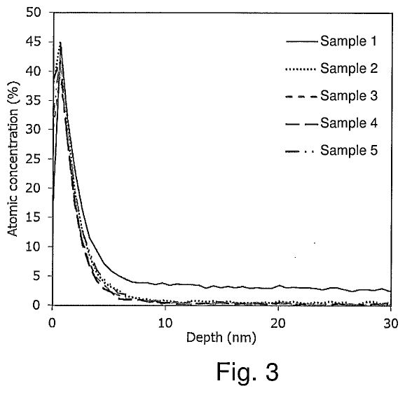

These data are illustrated by the graphs in FIG. 2 and FIG. 3.

SEM Image

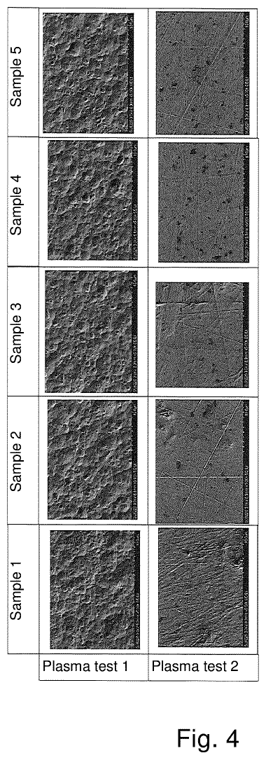

The SEM images of the structure surfaces after the standard plasma tests 1 and 2 were obtained as follows. That is, using the scanning electron microscope (SEM), evaluation was made in terms of the corrosion state of the plasma-exposed surface. “SU-8220, manufactured by Hitachi, Ltd.” was used for SEM. The acceleration voltage was 3 kV. The resulting photos are shown in FIG. 4.

Surface Roughness (Arithmetic Average Height Sa)

The structure's surface roughness after the standard plasma tests 1 and 2 was evaluated by Sa (arithmetic average height) in accordance with ISO 25178 using a laser microscope. “OLS 4500, manufactured by Olympus” was used as the laser microscope. MPLAPON 100 XLEXT was used as the objective lens, and the cut-off value λc was 25 μm. The results are summarized in the below table.

TABLE 5

| | Standard plasma |
|---|---|
| | test 1 |
| | Arithmetic average |
| Sample | height (μm) |
| 1 | 0.069 |
| 2 | 0.056 |
| 3 | 0.054 |
| 4 | 0.039 |
| 5 | 0.044 |
| 6 | 0.025 |

Assessment of the Results

On the basis of the above results, in Table 2 above, when the effect of plasma corrosion was small in both the standard plasma tests 1 and 2, this was assessed to be “⊚”, when the effect of plasma corrosion was small in any one of the standard plasma tests 1 and 2, this was assessed to be “◯”, and when there was the effect of plasma corrosion in both the standard plasma test conditions 1 and 2, this was assessed to be “X”.

In the above, the embodiments of the present invention have been described. However, the present invention is not limited to the above description. Any design modified with regard to these embodiments by those ordinarily skilled in the art is included in the claims of the present invention as long as such modification has the characteristics of the present invention. For example, those matters such as the form, size, material, and location of the structure, the substrate, etc. are not limited to those that are exemplified, but may be modified as appropriate. Each element described in the above-described embodiments may be combined as long as technically possible; and the resulting combination are included in the claims of the present invention as long as such combination includes the characteristics of the present invention.

### REFERENCE NUMERALS

10 Composite structure
15 Substrate
20 Structure
20a Structure surface

1. A composite structure comprising a substrate and a structure which is provided on the substrate and has a surface, wherein
the structure comprises Y₄Al₂O₉ as a main component, and an indentation hardness thereof is greater than 6.0 GPa.

2. The composite structure according to claim 1, wherein the indentation hardness is 9.0 GPa or greater.

3. The composite structure according to claim 1, wherein the indentation hardness is 10 GPa or greater.

4. The composite structure according to claim 1, wherein the indentation hardness is 11 GPa or greater.

5. The composite structure according to claim 1, wherein the average crystallite's size of the structure is less than 50 nm.

6. The composite structure according to claim 1, wherein the composite structure is configured to be used in an environment where low-particle generation is required.

7. The composite structure according to claim 6, wherein the composite structure is a member for a semiconductor manufacturing device.

8. A semiconductor manufacturing device comprising the composite structure according to claim 1.

9. The composite structure according to claim 2, wherein the average crystallite's size of the structure is less than 50 nm.

10. The composite structure according to claim 3, wherein the average crystallite's size of the structure is less than 50 nm.

11. The composite structure according to claim 4, wherein the average crystallite's size of the structure is less than 50 nm.
